(19) United States
(12) Patent Application Publication
(10) Pub. No.: US 2025/0266792 A1
(43) Pub. Date: Aug. 21, 2025

(54) LOW NOISE CRYSTAL OSCILLATOR

(71) Applicant: Realtek Semiconductor Corp., Hsinchu (TW)

(72) Inventor: Chia-Liang (Leon) Lin, Fremont, CA (US)

(21) Appl. No.: 18/443,607

(22) Filed: Feb. 16, 2024

(51) Int. Cl. H03B 5/12; H03B 1/04

(52) U.S. Cl. CPC H03B 5/1228; H03B 1/04; H03B 2200/0088

(57) ABSTRACT

A crystal oscillator having a voltage regulator configured to receive a first power supply voltage and output a second power supply voltage; a source follower configured to receive the second power supply voltage and output a third power supply voltage in accordance with a control voltage; a first inverter operating under the third power supply voltage and configured to receive a first oscillatory signal from a first node and output a second oscillatory signal at a second node; a second inverter operating under the third power supply voltage and configured to output a third oscillatory signal; a crystal placed across the first node and a second node; a first shunt capacitor configured to shunt the first node to ground; a second shunt capacitor configured to shunt the second node to ground; and a clocked lowpass filter configured to output the control voltage in accordance with the pulsed signal.

### BACKGROUND OF THE INVENTION

### Field of the Invention

The present invention generally relates to crystal oscillator and more particularly to crystal oscillator having low noise and good noise immunity.

### Description of Related Art

Persons of ordinary skill in the art understand terms and basic concepts related to microelectronics that are used in the context of this disclosure, such as “voltage,” “current,” “signal,” “oscillator,” “clock,” “capacitor,” “resistor,” “transistor,” “NMOST (n-channel metal-oxide semiconductor transistor),” “PMOST (p-channel metal-oxide semiconductor transistor),” “source,” “gate,” “drain,” “node,” “ground node,” “power supply node,” “inverter,” “switch,” “source follower,” “lowpass filter,” “operational amplifier,” and “noise.” Terms and basic concepts like these in the context of this present disclosure are apparent to those of ordinary skill in the art and thus will not be explained in detail.

Those of ordinary skill in the art can recognize a resistor symbol, a capacitor symbol, a switch symbol, an inverter symbol, an operational amplifier symbol, and a NAND gate symbol. Those of ordinary skill in the art can also recognize a PMOST (p-channel metal-oxide semiconductor transistor) symbol and a NMOST (n-channel metal-oxide semiconductor transistor) symbol, and can identify a “source” terminal, a “gate” terminal, a “drain” terminal, and a “body” terminal thereof. For brevity, in this present disclosure, in a context of reference to a NMOST or a PMOST, a “source terminal” is simply referred to as “source,” a “gate terminal” is simply referred to as “gate,” and a “drain terminal” is simply referred to as “drain.”

Those of ordinary skills in the art can read schematics of a circuit comprising resistors, capacitors, NMOST, PMOST, inverter, switch, operational amplifier, and so on, and do not need a detailed description about how one of them connects with another in the schematics.

As shown in FIG. 1, a conventional crystal oscillator 100 comprises: a crystal 160; two capacitors 161 and 162; an inverter 110 comprising NMOST 111 and PMOST 112; and a voltage regulator 150. Throughout this disclosure, “V_{DD}” denotes a power supply node. Crystal oscillator 100 is well known in the prior art and thus not described in detail here. Voltage regulator 150 is used to establish a supply voltage V_{SP} that is substantially independent of a voltage at the power supply node “V_{DD}”; this way, a noise at the power supply node “V_{DD}” can be effectively rejected. However, the voltage regulator 150 itself is usually a significant noise contributor. In other words, it provides noise immunity (against the noise from the power supply node “V_{DD}”) but unfortunately also introduces circuit noise of its own.

What is desired is a crystal oscillator with a voltage regulation scheme that can have good noise immunity against the noise from the power supply node without introducing much circuit noise of its own.

### BRIEF SUMMARY OF THIS INVENTION

An objective of embodiments of the invention is to have a voltage regulation scheme for a crystal oscillator that can provide noise immunity against a noise at a power supply node yet does not introduce much circuit noise.

In an embodiment, a crystal oscillator comprises: a voltage regulator configured to receive a first power supply voltage and output a second power supply voltage; a source follower configured to receive the second power supply voltage and output a third power supply voltage in accordance with a control voltage; a first inverter operating under the third power supply voltage and configured to receive a first oscillatory signal at a first node and output a second oscillatory signal at a second node; a second inverter operating under the third power supply voltage and configured to receive the second oscillatory signal and output a third oscillatory signal; a crystal placed across the first node and a second node; a first shunt capacitor configured to shunt the first node to ground; a second shunt capacitor configured to shunt the second node to ground; and a clocked lowpass filter configured to receive a reference voltage and output the control voltage in accordance with the pulsed signal, which is synchronous with the third oscillatory signal.

In an embodiment, a crystal oscillator comprises: a voltage regulator configured to receive a first power supply voltage and output a second power supply voltage; a source follower configured to receive the second power supply voltage and output a third power supply voltage in accordance with a control voltage; a first inverter operating under the third power supply voltage and configured to receive a first oscillatory signal at a first node and output a second oscillatory signal at a second node; a crystal placed across the first node and a second node; a first shunt capacitor configured to shunt the first node to ground; a second shunt capacitor configured to shunt the second node to ground; and a clocked lowpass filter configured to receive a reference voltage and output the control voltage in accordance with the pulsed signal, which is synchronous with the second oscillatory signal.

### BRIEF DESCRIPTION OF THE DRAWINGS

FIG. 1 shows a schematic diagram of a prior art crystal oscillator.

FIG. 2 shows a schematic diagram of a crystal oscillator in accordance with an embodiment of the present disclosure.

FIG. 3A shows a schematic diagram of a pulse generator that can be used in the crystal oscillator of FIG. 2.

FIG. 3B shows a timing diagram of the pulse generator of FIG. 3A.

FIG. 4 shows a schematic diagram of an embodiment of a reference voltage generator that can be used to generate the reference voltage used in the crystal oscillator of FIG. 2.

FIG. 5 shows a schematic diagram of an alternative embodiment of a reference voltage generator that can be used to generate the reference voltage used in the crystal oscillator of FIG. 2.

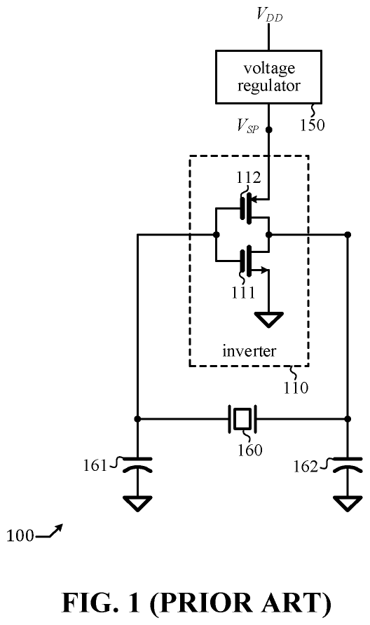

### DETAILED DESCRIPTION OF THIS INVENTION

The present invention relates to crystal oscillator. While the specification describes several example embodiments of the invention considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the invention.

A source follower can be embodied by an NMOST (n-channel metal oxide semiconductor transistor), wherein an output voltage is established at its source in accordance with a control voltage at its gate under a power supply provided at its drain.

An NMOST is said to be configured in a diode-connect topology when its gate and its drain are connected to the same node.

A circuit is a collection of a transistor, a capacitor, an inductor, a resistor, and/or other electronic devices inter-connected in a certain manner to embody a certain function. A network is a circuit or a collection of circuits configured to embody a certain function.

In this present disclosure, a “circuit node” is simply referred to as a “node” for short, as the meaning is clear from a context of microelectronics and won't cause confusion.

In this present disclosure, a signal is a voltage of a variable level that can vary with time. A (voltage) level of a signal at a moment represents a state of the signal at that moment.

A logical signal is a signal of two states: a low state and a high state. The low state is also referred to as a “0” state, while the high stage is also referred to as a “1” state. Regarding a logical signal Q, “Q is high” or “Q is low,” means “Q is in the high state” or “Q is in the low state.” Likewise, “Q is 1” or “Q is 0,” means “Q is in the 1 state” or “Q is in the 0 state.”

When a logical signal toggles from low to high, it undergoes a low-to-high transition and a rising edge occurs. When a logical signal toggles from high to low, it undergoes a high-to-low transition and a falling edge occurs. A pulse of a logical signal starts at a rising edge and ends at a subsequent falling edge.

A first logical signal is said to be a logical inversion of a second logical signal if the first logical signal and the second logical signal are always in opposite states. That is, when the first logical signal is 0 (low), the second logical signal is 1 (high); when the first logical signal is 1 (high), the second logical signal is 0 (high). When a first logical signal is a logical inversion of a second logical signal, the first logical signal and the second logical signal are said to be complementary to one another.

A clock is a logical signal that cyclically toggles back and forth between a low state and a high state.

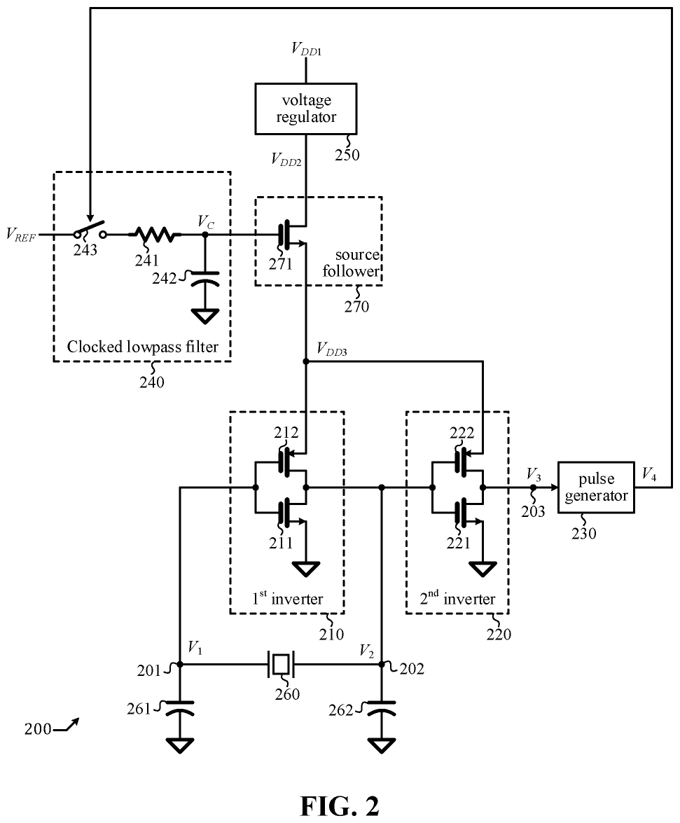

As shown in FIG. 2, a crystal oscillator 200 in accordance with an embodiment of the present invention comprises: a voltage regulator 250 configured to receive a first power supply voltage V_{DD1} and output a second power supply voltage V_{DD2}; a source follower 270 configured to output a power third supply voltage V_{DD3} in accordance with a control voltage V_{C} under the second power supply voltage V_{DD2}; a first inverter 210 comprising NMOST 211 and PMOST 212, operating under the third power supply voltage V_{DD3}, and configured to receive a first oscillatory signal V₁ at a first node 201 and output a second oscillatory signal V₂ at a second node 202; a crystal placed across the first node 201 and the second node 202; a first shunt capacitor 261 configured to shunt the first node 201 to ground; a second shunt capacitor 262 connected to shunt the second node 202 to ground; a second inverter 220 comprising NMOST 221 and PMOST 222, operating under the third power supply voltage V_{DD3}, and configured to receive the second oscillatory signal V₂ and output a third oscillatory signal V₃ at a third node 203; a pulse generator 230 configured to receive the third oscillatory signal V₃ and output a pulsed signal V₄; and a clocked lowpass filter 240 configure to receive a reference voltage V_{REF} and output the control signal V_{C} in accordance with the pulsed signal V₄.

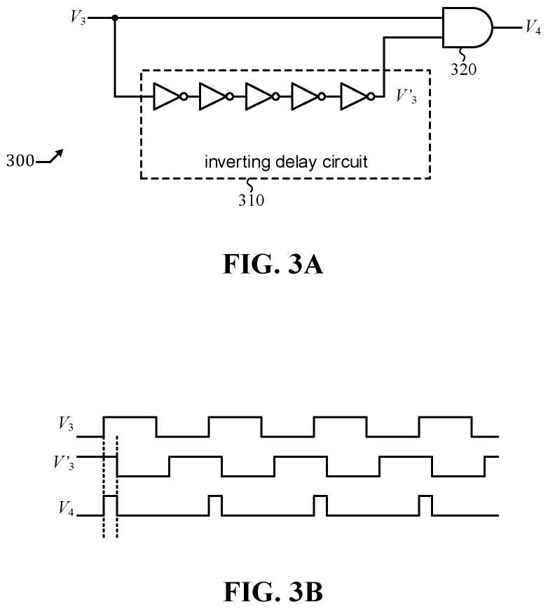

A schematic diagram of a pulse generator 300 that can be used to embody the pulse generator 230 is shown in FIG. 3A. The pulse generator 300 comprises an inverting delay circuit 310 configured to receive V₃ and output an inverted delay signal V′₃, and an AND gate 320 configured to receive V₃ and V′₃ and output V₄. The inverting delay circuit 310 comprises a cascade of an odd number of inverters (by way of example but not limitation, five inverters are shown). A timing diagram of the pulse generator 300 is shown in FIG. 3B. As shown, V′₃ is a delayed and then inverted version of V₃, and V₄ is a pulsed signal, where a first (or rising) edge of V₄ approximately aligns with a first (or rising) edge of V₃, a second (or falling) edge of V₄ approximately aligns with a second (or falling) edge of V′₃, and a pulse width of V₄ is equal to a delay of V′₃ with respect to V₃. The pulse generator 300 and the timing diagram of FIG. 3B can be easily understood by those of ordinary skill in the art and thus not further explained.

The crystal 260 embodies a resonant network that establishes oscillation of V₁ and V₂, while the first shunt capacitor 261, the second shunt capacitor 262, and the 1^{st} inverter 210 form a regenerative network that sustains the oscillation; this part is well known in the prior art and thus not further explained. The 2^{nd} inverter 220 serves as a buffer. Both the 1^{st} inverter 201 and the 2^{nd} inverter 220 operate under the third power supply voltage V_{DD3}, which is converted from the second power supply voltage V_{DD2} by the source follower 270 comprising an NMOST 271, wherein V_{DD3}, V_{C}, and V_{DD2} are voltages of a source, a gate, and a drain, respectively, of NMOST 271. The second power supply voltage V_{DD2} is converted from the first power supply voltage V_{DD1} by the voltage regulator 250. The third power supply voltage V_{DD3} is approximately equal to the control voltage V_{C} minus a gate-to-source voltage of NMOST 271 and is highly insensitive to the second power supply voltage V_{DD2}. In other words, source follower 270 provides an effective voltage regulation, so that not only a noise from the first power supply voltage V_{DD1} but also a circuit noise generated by the voltage regulator 250 can be effectively suppressed. A noise at the control voltage V_{C}, however, will result in a noise at the third power supply voltage V_{DD3}.

To address this issue, the clocked lowpass filter 240 is used to filter the reference voltage V_{REF} into the control voltage V_{C}. The clocked lowpass filter 240 comprises: a switch 243 controlled by V₄, a serial resistor 241, and a shunt capacitor 242. The serial resistor 241 and the shunt capacitor 242 forms a lowpass filter; this can be easily understood by those of ordinary skill in the art and thus not further explained. The switch 243 is turned on in a pulsed manner, so that a DC (direct current) level of V_{C} is equal to a DC level of V_{REF}, while an AC (alternate current) noise of V_{REF} can be rejected. The serial resistor 241 is a noise contributor, but it can induce noise onto V_{C} only when the switch 243 is turned on. Due to the pulse nature of V₄, the noise of the serial resistor 241 can be reduced. In an embodiment, a pulse width of the pulsed signal V₄ is substantially smaller than a period of the third oscillatory signal V₃ to allow a substantial noise reduction; in other words, a duty cycle of V₄ is substantially smaller than 100%. For instance, a duty cycle of V₄ is 10%, and the serial resistor 241 can induce noise onto V_{C} only 10% of the time, effectively reducing the noise by 90%.

The pulse nature of the clocked lowpass filter 240 introduces a disturbance to the V_{C}, thus disturbing V₁, V₂, and V₃. However, the disturbance is periodic of the same periodicity of V₁, V₂, and V₃. In other words, it is synchronous to the crystal oscillation, can be considered as part of the oscillation, and is therefore not a true disturbance.

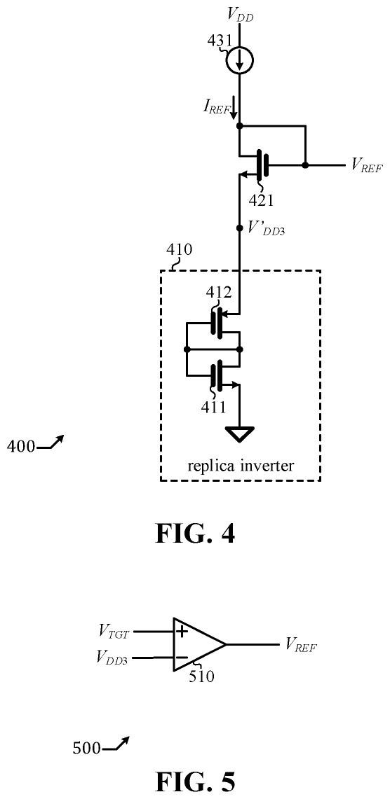

As shown in FIG. 4, in an embodiment, the reference voltage V_{REF} is generated using a reference voltage generator 400 comprising: a current source 431, a diode-connect NMOST 421, and a replica inverter 410 comprising NMOST 411 and PMOST 412. The replica inverter 410 mimics the 1^{st} inverter 210 and the 2^{nd} inverter 220 (with a scaling down of the device width); the current source 431 outputs a reference current I_{REF} that mimics a current drawn by the 1^{st} inverter 210 and the 2^{nd} inverter 220 (with a scaling down ratio); and the diode-connect NMOST 421 mimics NMOST 271 (with a scaling down of the device width). As long as a current drawn by 1^{st} inverter 210 and 2^{nd} inverter 220 can be estimated, a value of the reference current I_{REF} of the current source 431 can be chosen accordingly so that a reference power supply voltage V′_{DD3} of the replica inverter 410 can be approximately equal to the third power supply voltage V_{DD3} and a gate-to-source voltage of NMOST 421 can be approximately equal to a gate-to-source voltage of NMOST 271.

As shown in FIG. 5, in an alternative embodiment, the reference voltage V_{REF} is generated using an alternative voltage generator 500 comprising an operational amplifier 510 configured to output V_{REF} in accordance with a difference between a target voltage V_{TGT} and the third power supply voltage V_{DD3}. The operational amplifier 510, the clocked lowpass filter 240, and the source follower 270 form a negative feedback control loop to adjust V_{REF} to cause V_{DD3} to be approximately equal to V_{TGT}. Operational amplifiers are well understood by those of ordinary skill in the art and thus not described in detail.

The 2^{nd} inverter 220 serves a purpose of complementing the 1^{st} inverter 210 so as to present a more balanced load to the third power supply voltage V_{DD3}. This is beneficial but not absolutely needed. In another embodiment, the 2^{nd} inverter 220 is removed, and the pulse generator receives V₂ instead of V₃.

Those skilled in the art will readily observe that numerous modifications and alterations of the device and method may be made while retaining the teachings of the disclosure. Accordingly, the above disclosure should not be construed as limited only by the metes and bounds of the appended claims.

What is claimed is:

1. A crystal oscillator comprising:
a voltage regulator configured to receive a first power supply voltage and output a second power supply voltage;
a source follower configured to receive the second power supply voltage and output a third power supply voltage in accordance with a control voltage;
a first inverter operating under the third power supply voltage and configured to receive a first oscillatory signal at a first node and output a second oscillatory signal at a second node;
a second inverter operating under the third power supply voltage and configured to receive the second oscillatory signal and output a third oscillatory signal;
a crystal placed across the first node and the second node;
a first shunt capacitor configured to shunt the first node to ground;
a second shunt capacitor configured to shunt the second node to the ground; and
a clocked lowpass filter configured to receive a reference voltage and output the control voltage in accordance with a pulsed signal, which is synchronous with the third oscillatory signal.

2. The crystal oscillator of claim 1, wherein a first edge of the pulsed signal approximately aligns with a first edge of the third oscillatory signal, and a pulse width of the pulsed signal is substantially smaller than a period of the third oscillatory signal.

3. The crystal oscillator of claim 2, wherein the pulsed signal is generated by a pulse generator comprising: an inverting delay circuit configured to receive the third oscillatory signal and output an inverted delay signal that is an inversion of a delayed version of the third oscillatory signal; and an NAND gate configured to receive the third oscillatory signal, the inverted delay signal and output the pulsed signal.

4. The crystal oscillator of claim 1, wherein the reference voltage is generated by a reference generator comprising: a current source configured to output a reference current; a NMOST (n-channel metal-oxide semiconductor transistor) configured in a diode connect topology to receive the reference current from a drain of the NMOST and establish a reference supply voltage at a source of the NMOST; and a replica inverter operating under the reference supply voltage.

5. The crystal oscillator of claim 1, wherein the reference voltage is generated using an operational amplifier configured to output the reference voltage in accordance with a difference between a target voltage and the third power supply voltage.

6. The crystal oscillator of claim 1, wherein the clocked lowpass filter comprises a serial connection of a switch controlled by the pulsed signal and a serial resistor, and a shunt capacitor.

7. A crystal oscillator comprising:
a voltage regulator configured to receive a first power supply voltage and output a second power supply voltage;
a source follower configured to receive the second power supply voltage and output a third power supply voltage in accordance with a control voltage;
a first inverter operating under the third power supply voltage and configured to receive a first oscillatory signal at a first node and output a second oscillatory signal at a second node;
a crystal placed across the first node and the second node;
a first shunt capacitor configured to shunt the first node to ground;
a second shunt capacitor configured to shunt the second node to the ground; and
a clocked lowpass filter configured to receive a reference voltage and output the control voltage in accordance with a pulsed signal, which is synchronous with the second oscillatory signal.

8. The crystal oscillator of claim 7, wherein a first edge of the pulsed signal approximately aligns with a first edge of the second oscillatory signal, and a pulse width of the pulsed signal is substantially smaller than a period of the second oscillatory signal.

9. The crystal oscillator of claim 7, wherein the reference voltage is generated by a reference generator comprising: a current source configured to output a reference current; a NMOST (n-channel metal-oxide semiconductor transistor) configured in a diode connect topology to receive the reference current from a drain of the NMOST and establish a reference supply voltage at a source of the NMOST; and a replica inverter operating under the reference supply voltage.

10. The crystal oscillator of claim 7, wherein the reference voltage is generated using an operational amplifier configured to output the reference voltage in accordance with a difference between a target voltage and the third power supply voltage.
